(19) United States
(12) Patent Application Publication
(10) Pub. No.: US 2026/0020309 A1
(43) Pub. Date: Jan. 15, 2026

(54) SEMICONDUCTOR DEVICE AND METHOD FOR MANUFACTURING SEMICONDUCTOR DEVICE

(71) Applicant: Nuvoton Technology Corporation Japan, Kyoto (JP)

(72) Inventor: Yusuke KANDA, Toyama (JP)

(21) Appl. No.: 19/333,037

(22) Filed: Sep. 18, 2025

Related U.S. Application Data
(63) Continuation of application No. PCT/JP2024/012638, filed on Mar. 28, 2024.
(60) Provisional application No. 63/493,030, filed on Mar. 30, 2023.

(51) Int. Cl. H10D 64/00; H10D 30/47

(52) U.S. Cl. CPC H10D 64/118; H10D 30/475

(57) ABSTRACT

A semiconductor device includes: an electron transport layer; an electron supply layer provided above the electron transport layer and having a band gap greater than a band gap of the electron transport layer; a gate electrode provided above the electron supply layer; a contact layer embedded in recessed portions that penetrate through the electron supply layer, at positions between which the gate electrode is provided; a first insulating layer provided above a portion of the electron supply layer in which the gate electrode is not provided; and a second insulating layer provided above the first insulating layer, in contact with the contact layer, and not in contact with the gate electrode. A coefficient of linear thermal expansion of the second insulating layer is greater than a coefficient of linear thermal expansion of the electron supply layer.

### CROSS REFERENCE TO RELATED APPLICATIONS

This is a continuation application of PCT International Patent Application No. PCT/JP2024/012638 filed on Mar. 28, 2024, designating the United States of America, which is based on and claims priority of U.S. Provisional Patent Application No. 63/493,030 filed on Mar. 30, 2023. The entire disclosures of the above-identified applications, including the specifications, drawings and claims are incorporated herein by reference in their entirety.

### FIELD

The present disclosure relates to a semiconductor device and a method for manufacturing the same, and in particular to a group III nitride semiconductor device that includes a group III nitride semiconductor and a method for manufacturing the same.

### BACKGROUND

A group III nitride semiconductor device that includes a group III nitride semiconductor or in particular, gallium nitride (GaN) or aluminum gallium nitride (AlGaN) has a high breakdown voltage since its material has a wide band gap. In the group III nitride semiconductor device, a heterostructure of AlGaN and GaN, for instance, can be readily formed.

In an AlGaN/GaN heterostructure, highly concentrated electrons (a two-dimensional electron gas) are generated on a GaN layer side of an interface between an AlGaN layer and a GaN layer so that a channel of a two-dimensional electron gas layer is formed, because of a difference between piezo polarization caused by a difference in lattice constant between the materials and spontaneous polarization of AlGaN and GaN. A group III nitride semiconductor device that utilizes a channel of such a two-dimensional electron gas has a relatively high electron saturation velocity, relatively high insulation resistance, and a relatively high thermal conductivity, and thus is applied to high-frequency power devices, for instance.

In order to enhance properties of such a group III nitride semiconductor device, a contact between an ohmic electrode and the two-dimensional electron gas layer inside the group III nitride semiconductor device (hereinafter, referred to as “ohmic contact”) and a parasitic resistance component such as a resistance of a channel made by a two-dimensional electron gas may be reduced as much as possible.

Conventionally, a technique of reducing an ohmic contact resistance in a group III nitride semiconductor device that utilizes a channel made by a two-dimensional electron gas has been proposed. For example, Patent Literature (PTL) 1 has disclosed a technique of forming a recessed portion that penetrates through an electron supply layer made of AlGaN (hereinafter, referred to as a “penetrating recessed portion”) in a portion in which an ohmic electrode is to be formed inside the group III nitride semiconductor device, and forming a contact layer by selectively regrowing a low energy barrier material such as n-GaN or n-InGaN, in order to reduce an ohmic contact resistance.

### CITATION LIST

### Patent Literature

PTL 1: Japanese Unexamined Patent Application Publication No. 2019-114581

### SUMMARY

### Technical Problem

However, if a penetrating recessed portion is formed in an electron supply layer as shown by the technique disclosed by PTL 1, a two-dimensional electron gas layer and the contact layer embedded in the penetrating recessed portion are essentially connected by points, which is inevitable. Furthermore, if a penetrating recessed portion is formed in the electron supply layer, not only crystal defects are caused at an interface between the contact layer and a two-dimensional electron gas layer (a channel layer) made of GaN when the penetrating recessed portion is provided, but also a region in which a carrier (electron) concentration lowers is generated at the interface in a portion of an electron supply layer adjacent to the lateral surface of the penetrating recessed portion due to pollutants in the atmosphere and a bond defect so that the maximum drain current decreases, which is a problem.

The present disclosure has been conceived in view of such a problem, and provides a semiconductor device that can reduce a decrease in the maximum drain current and a method for manufacturing the same.

### Solution to Problem

In order to provide such a semiconductor device, a first semiconductor device according to an aspect of the present disclosure includes: an electron transport layer; an electron supply layer provided above the electron transport layer and having a band gap greater than a band gap of the electron transport layer; a gate electrode provided above the electron supply layer; a source-side contact layer and a drain-side contact layer that are embedded in recessed portions that penetrate through the electron supply layer, at positions between which the gate electrode is provided; a first insulating layer provided above a portion of the electron supply layer in which the gate electrode is not provided; and a second insulating layer provided above the first insulating layer, in contact with at least one of the source-side contact layer or the drain-side contact layer, and not in contact with the gate electrode. A coefficient of linear thermal expansion of the second insulating layer is greater than a coefficient of linear thermal expansion of the electron supply layer.

A second semiconductor device according to an aspect of the present disclosure includes: an electron transport layer; an electron supply layer provided above the electron transport layer and having a band gap greater than a band gap of the electron transport layer; a gate electrode provided above the electron supply layer; a contact layer embedded in recessed portions that penetrate through the electron supply layer, at positions between which the gate electrode is provided; a source electrode or a drain electrode provided above the contact layer; a first insulating layer provided above a portion of the electron supply layer in which the gate electrode is not provided; and a second insulating layer provided above the first insulating layer, in contact with the contact layer, and not in contact with the gate electrode. The second insulating layer includes an oxynitride layer or a composite layer made of an oxide and a nitride.

A method for manufacturing a semiconductor device according to an aspect of the present disclosure includes: a process of forming, above an electron transport layer, an electron supply layer having a band gap greater than a band gap of the electron transport layer; forming a first insulating layer above the electron supply layer without exposure to atmosphere; forming a penetrating recessed portion that penetrates through the first insulating layer and the electron supply layer and reaches up to the electron transport layer; embedding and forming a contact layer in the penetrating recessed portion; forming a second insulating layer above the first insulating layer; forming a source electrode and a drain electrode above and in contact with the contact layer; forming a first insulating layer exposed portion by removing a portion of the second insulating layer other than a portion in contact with the contact layer to expose the first insulating layer; and forming a gate electrode by removing a portion of the first insulating layer exposed portion that is separated from the second insulating layer. The second insulting layer includes an oxynitride layer or a composite layer made of an oxide and a nitride.

### Advantageous Effects

According to the present disclosure, a semiconductor device that can reduce a decrease in the maximum drain current can be obtained.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a cross-sectional view illustrating a configuration of a semiconductor device according to Embodiment 1.

FIG. 2 is a schematic diagram illustrating a conduction band of an energy band of the semiconductor device according to Embodiment 1.

FIG. 3A is a cross-sectional view illustrating a process of forming a semiconductor layered structure, a first insulating layer, and a second insulating layer in a method for manufacturing the semiconductor device according to Embodiment 1.

FIG. 3B is a cross-sectional view illustrating a process of forming penetrating recessed portions in the method for manufacturing the semiconductor device according to Embodiment 1.

FIG. 3C is a cross-sectional view illustrating a process of forming a contact layer in the method for manufacturing the semiconductor device according to Embodiment 1.

FIG. 3D is a cross-sectional view illustrating a process of forming a source electrode and a drain electrode in the method for manufacturing the semiconductor device according to Embodiment 1.

FIG. 3E is a cross-sectional view illustrating a process of patterning a second insulating layer in the method for manufacturing the semiconductor device according to Embodiment 1.

FIG. 3F is a cross-sectional view illustrating a process of forming a gate electrode in the method for manufacturing the semiconductor device according to Embodiment 1.

FIG. 4 is a cross-sectional view illustrating a configuration of a semiconductor device according to a variation of Embodiment 1.

FIG. 5 is a cross-sectional view illustrating a configuration of a semiconductor device according to Embodiment 2.

FIG. 6 is a schematic diagram illustrating a conduction band of an energy band of the semiconductor device according to Embodiment 2.

FIG. 7A is a cross-sectional view illustrating a process of forming a semiconductor layered structure and a first insulating layer in a method for manufacturing the semiconductor device according to Embodiment 2.

FIG. 7B is a cross-sectional view illustrating a process of forming penetrating recessed portions in the method for manufacturing the semiconductor device according to Embodiment 2.

FIG. 7C is a cross-sectional view illustrating a process of forming a contact layer in the method for manufacturing the semiconductor device according to Embodiment 2.

FIG. 7D is a cross-sectional view illustrating a process of forming a second insulating layer in the method for manufacturing the semiconductor device according to Embodiment 2.

FIG. 7E is a cross-sectional view illustrating a process of forming a source electrode and a drain electrode in the method for manufacturing the semiconductor device according to Embodiment 2.

FIG. 7F is a cross-sectional view illustrating a process of patterning a second insulating layer in the method for manufacturing the semiconductor device according to Embodiment 2.

FIG. 7G is a cross-sectional view illustrating a process of forming a gate electrode in the method for manufacturing the semiconductor device according to Embodiment 2.

### DESCRIPTION OF EMBODIMENTS

In the following, embodiments of the present disclosure are described with reference to the drawings. The embodiments shown herein show specific examples of the present disclosure. Thus, the numerical values, shapes, elements, the arrangement and connection of the elements, steps (processes), and the order of processing the steps, for instance, described in the following embodiments are examples, and thus are not intended to limit the present disclosure. Among the elements in the following embodiments, elements not recited in any of the independent claims defining the most generic concept of the present disclosure are described as optional elements.

The drawings are schematic diagrams, and do not necessarily provide strictly accurate illustration. Accordingly, scales, for instance, are not necessarily the same in the drawings. In the drawings, the same sign is given to substantially the same configuration, and a redundant description thereof is omitted or simplified.

In this specification, the terms “above”, “upward”, “below”, and “downward” in the configuration of a semiconductor device do not indicate upward (vertically upward) or downward (vertically downward) in the absolute recognition of space, but are terms defined by a relative positional relation based on the stacking order in a layered structure. Furthermore, the terms “above” and “below” are used not only when two elements are spaced apart from each other and another element is present therebetween, but also when two elements are disposed in close contact with each other so that the two elements are touching each other.

In the specification and the drawings, the x axis, the y axis, and the z axis represent three axes of a three-dimensional orthogonal coordinate system. In the embodiments, the two axes parallel to the upper surface of a substrate included in a semiconductor device are the x axis and the y axis, and the direction orthogonal to this upper surface is the z-axis direction. In the embodiments described below, the z-axis positive direction may be stated as upward and the z-axis negative direction may be stated as downward. Note that in the specification, a “plan view” refers to a state when the substrate included in the semiconductor device is viewed in the z-axis positive direction.

### Embodiment 1

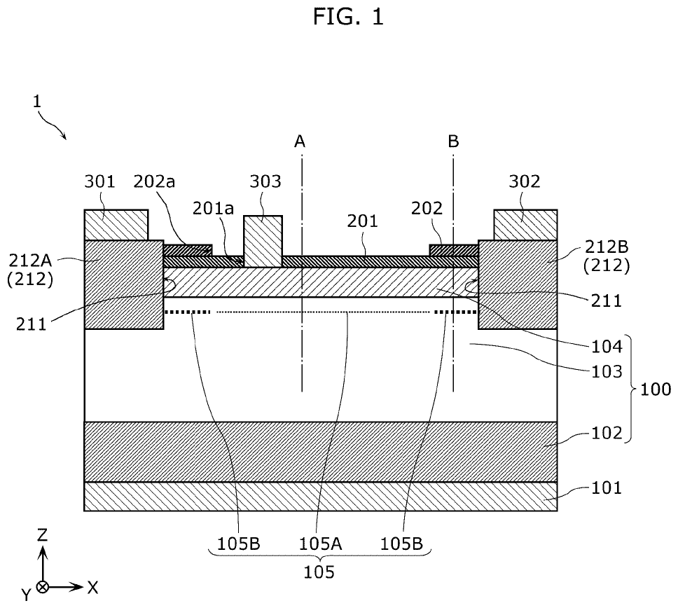

First, semiconductor device 1 according to Embodiment 1 is described with reference to FIG. 1. FIG. 1 is a cross-sectional view illustrating a configuration of semiconductor device 1 according to Embodiment 1.

In the present embodiment, the case in which semiconductor device 1 is a high electron mobility transistor (HEMT) that includes a Schottky junction gate structure is described.

As illustrated in FIG. 1, semiconductor device 1 includes substrate 101, buffer layer 102, electron transport layer 103, electron supply layer 104, first insulating layer 201, second insulating layer 202, source electrode 301, drain electrode 302, and gate electrode 303. Buffer layer 102, electron transport layer 103, and electron supply layer 104 constitute semiconductor layered structure 100 made of semiconductor materials.

Substrate 101 is a silicon substrate made of Si, for example. In the present embodiment, substrate 101 is a silicon substrate made of a Si monocrystal having a principal surface that is the (111) plane. Note that substrate 101 is not limited to a silicon substrate, but may be a substrate made of sapphire, SiC, GaN, or AlN, for instance, that is a ground for forming a nitride semiconductor layer. The resistivity of substrate 101 is at least 1 kΩ, for example. Note that a substrate whose resistivity is at most 20 Ω may be used as substrate 101.

Buffer layer 102 is provided above substrate 101. Buffer layer 102 is a group III nitride semiconductor layer having a structure of stacked AlN and AlGaN layers and having a thickness of 2 μm. In this case, an AlN layer and an AlGaN layer may form one pair, and 20 to 100 pairs of the layers may be stacked. Buffer layer 102 may have a superlattice structure in which a plurality of Al₁₋ₐGaₐN (0≤a<0.8) layers are stacked. Other than those, buffer layer 102 may include a single layer or multiple layers made of one or more group III nitride semiconductors such as InGaN and AlInGaN. Note that the resistance of buffer layer 102 may be increased by setting the carbon concentration of buffer layer 102 to at least 1×10¹⁹ atoms/cm³.

Electron transport layer 103 is provided above buffer layer 102. In the present embodiment, electron transport layer 103 is a GaN layer made of GaN and having a thickness of 150 nm, for example. Note that the group III nitride semiconductor included in electron transport layer 103 is not limited to GaN. Electron transport layer 103 may be made of a group III nitride semiconductor such as InGaN, AlGaN, or AlInGaN. Electron transport layer 103 may include n-type impurities.

Electron supply layer 104 is provided above electron transport layer 103. Electron supply layer 104 has a bigger band gap than the band gap of electron transport layer 103. In the present embodiment, electron supply layer 104 is an AlGaN layer made of AlGaN having the Al composition ratio of 30% and having a thickness of 13 nm, for example. A highly concentrated two-dimensional electron gas is generated on the electron transport layer 103 side of the heterointerface between electron supply layer 104 and electron transport layer 103, and a channel of two-dimensional electron gas layer 105 is formed. Thus, semiconductor device 1 has two-dimensional electron gas layer 105. Although details are described later, two-dimensional electron gas layer 105 includes first two-dimensional electron gas layer 105A and second two-dimensional electron gas layer 105B having different electron concentrations of the two-dimensional electron gas.

Note that the Al composition ratio of electron supply layer 104 made of AlGaN is not limited to 30%. The Al composition ratio of electron supply layer 104 may be in a range of 20% to 100%. Furthermore, the group III nitride semiconductor included in electron supply layer 104 is not limited to AlGaN. Electron supply layer 104 may be made of a group III nitride semiconductor that contains In, such as AlInGaN. Electron supply layer 104 may include n-type impurities.

A cap layer may be provided above electron supply layer 104. As a cap layer, a GaN layer having a thickness of about 1 nm to 2 nm and made of GaN, for example, can be used. A spacer layer may be provided between electron transport layer 103 and electron supply layer 104. An AlN layer made of AlN and having a thickness of about 1 nm, for example, can be used as the spacer layer.

First insulating layer 201 is provided above electron supply layer 104. First insulating layer 201 is an SiN layer made of SiN. In the present embodiment, first insulating layer 201 is an SiN layer made of in-situ SiN and having a thickness of 2 nm. Note that in-situ means being formed without exposure to the atmosphere. Thus, first insulating layer 201 made of in-situ SiN is an SiN layer formed without being exposed to the atmosphere after electron supply layer 104 is formed.

By making first insulating layer 201 using in-situ SiN in this manner, maldistribution of oxygen at the interface between first insulating layer 201 and electron supply layer 104 can be eliminated. By eliminating maldistribution of oxygen at the interface between first insulating layer 201 and electron supply layer 104, the occurrence of an interface state can be reduced. Accordingly, an increase in potential at the interface can be reduced and a decrease in electron concentration of a two-dimensional electron gas can be reduced.

The thickness of first insulating layer 201 may be at least 2 nm and at most 30 nm. By setting the thickness of first insulating layer 201 to at least 2 nm, maldistribution of oxygen caused by natural oxidation at the interface between first insulating layer 201 and electron supply layer 104 can be reduced. On the other hand, if the thickness of first insulating layer 201 exceeds 30 nm, a wafer warps when semiconductor device 1 is produced, so that the quality of semiconductor device 1 decreases. Accordingly, the thickness of first insulating layer 201 may be at most 30 nm. Thus, the warping of a wafer can be reduced by setting the thickness of first insulating layer 201 to 30 nm or less.

First insulating layer 201 may not contain oxygen. If first insulating layer 201 contains oxygen, the interface state at the interface between first insulating layer 201 and electron supply layer 104 increases, and the potential at the interface between first insulating layer 201 and electron supply layer 104 increases and the electron concentration of the two-dimensional electron gas decreases. Since first insulating layer 201 does not contain oxygen, a decrease in electron concentration of the two-dimensional electron gas can be reduced.

Opening portion 201a is provided in first insulating layer 201. Opening portion 201a is formed in a region of first insulating layer 201 in which gate electrode 303 is to be provided. Thus, first insulating layer 201 is provided above a portion of electron supply layer 104 in which gate electrode 303 is not provided. In the present embodiment, gate electrode 303 provided in opening portion 201a of first insulating layer 201 reaches electron supply layer 104. Thus, gate electrode 303 is in contact with electron supply layer 104.

Penetrating recessed portions 211 are provided in electron supply layer 104. In the present embodiment, penetrating recessed portions 211 are provided, penetrating through first insulating layer 201 and electron supply layer 104 to reach electron transport layer 103. Penetrating recessed portions 211 reach up to the inner part of electron transport layer 103, and recessed portions are provided in electron transport layer 103.

The distance between the upper surface of electron transport layer 103 and the lowest bottom portion of the bottom surface of penetrating recessed portion 211 may be at most 10 nm. As an example, the distance between the upper surface of electron transport layer 103 and the lowest bottom portion of the bottom surface of penetrating recessed portion 211 is 5 nm. The angle of elevation from the center portion of the bottom surface of penetrating recessed portion 211 to the lateral portion thereof may be at most 10 degrees, or may optionally be at most 5 degrees. By adopting such a configuration, the occurrence of crystal defects on the lateral surfaces of penetrating recessed portions 211 when penetrating recessed portions 211 are formed by dry etching can be reduced, and a decrease in maximum drain current can be reduced.

Penetrating recessed portions 211 are provided in correspondence with regions in which source electrode 301 and drain electrode 302 are to be provided. Specifically, a pair of penetrating recessed portions 211 are provided facing each other with gate electrode 303 being provided therebetween.

Contact layer 212 is provided in penetrating recessed portions 211. Contact layer 212 is provided being embedded in penetrating recessed portions 211. Contact layer 212 provided in one of the pair of penetrating recessed portions 211 is source-side contact layer 212A, and contact layer 212 provided in the other of the pair of penetrating recessed portions 211 is drain-side contact layer 212B. Source-side contact layer 212A and drain-side contact layer 212B are provided in positions between which gate electrode 303 is provided.

Contact layer 212 is an n-GaN layer made of n-type GaN, for example. Note that the material of contact layer 212 is not limited to n-type GaN, and contact layer 212 may be made of a group III nitride semiconductor such as InGaN, AlGaN, or AlInGaN and containing a donor such as Si or Ge as n-type impurities, or may be configured of a multi-layer electrode film having a layered structure in which Ti and Al layers are stacked in this order. Furthermore, contact layer 212 may be made using a material such as Ti, Ta, Al, Au, Hf, Ru, or Cu.

Source electrode 301 and drain electrode 302 are provided above contact layer 212. Specifically, source electrode 301 is provided above source-side contact layer 212A, whereas drain electrode 302 is provided above drain-side contact layer 212B. Source electrode 301 and drain electrode 302 face each other with gate electrode 303 being provided therebetween. Source electrode 301 and drain electrode 302 are configured of, for example, a multi-layer electrode film having a layered structure in which a Ti film having a thickness of 30 nm and an Al film having a thickness of 200 nm are stacked in this order, but are not limited to these. Source electrode 301 and drain electrode 302 may be made using at least one of Ti, Ta, W, Al, Au, Hf, Ru, or Cu.

Gate electrode 303 is provided above electron supply layer 104. Specifically, gate electrode 303 is provided above electron supply layer 104 via opening portion 201a provided in first insulating layer 201.

Gate electrode 303 is a multi-layer electrode film having a layered structure in which a TiN film and an Al film are stacked in this order, for example. Note that gate electrode 303 is not limited to a layered structure of a TiN film and an Al film, but may be made of at least one of a transition metal nitride or a transition metal carbide. Specifically, gate electrode 303 may be made of TiN, WN, TaN, or HfN. Gate electrode 303 may be made using Ti, Ta, W, Al, Pd, Pt, Hf, Ru, or Cu, may be a chemical compound that contains such an element, or may be a multi-layer electrode film having a structure of stacked layers. Note that another insulating layer or a p-type nitride semiconductor layer may be provided between electron supply layer 104 and gate electrode 303.

Second insulating layer 202 is provided above first insulating layer 201. In the present embodiment, second insulating layer 202 is in contact with first insulating layer 201.

Second insulating layer 202 is provided in contact with contact layer 212. Specifically, second insulating layer 202 is in contact with at least one of source-side contact layer 212A or drain-side contact layer 212B. Thus, second insulating layer 202 may be in contact with either one of source-side contact layer 212A or drain-side contact layer 212B. In the present embodiment, second insulating layer 202 is in contact with both source-side contact layer 212A and drain-side contact layer 212B. Note that second insulating layer 202 may be divided into a plurality of portions. In this case, one of the portions of second insulating layer 202 may be in contact with source-side contact layer 212A, and another one of the portions of second insulating layer 202 may be in contact with drain-side contact layer 212B.

Furthermore, second insulating layer 202 is provided not in contact with gate electrode 303. Thus, second insulating layer 202 is provided separately from gate electrode 303. Thus, second insulating layer 202 may be provided not too close to gate electrode 303.

In a cross-sectional view, the width of second insulating layer 202 in contact with one of source-side contact layer 212A or drain-side contact layer 212B may be smaller than the distance between the gate-side end portion of second insulating layer 202 and the second insulating layer 202 side end portion of gate electrode 303. Specifically, the width of second insulating layer 202 may be at most 1 μm. In particular, the width of second insulating layer 202 in contact with drain-side contact layer 212B (second insulating layer 202 closer to drain electrode 302) may be at most 1 μm. By adopting such a configuration, leakage current between gate electrode 303 and drain electrode 302 can be reduced. Note that if second insulating layer 202 closer to drain electrode 302 is separated from gate electrode 303, second insulating layer 202 closer to source electrode 301 may be in contact with gate electrode 303. By adopting such a configuration, access resistance between source electrode 301 and gate electrode 303 can be decreased, and thus maximum drain current can be increased.

Opening portion 202a is provided in second insulating layer 202. Opening portion 202a is provided in a region of second insulating layer 202 in which gate electrode 303 is to be provided. The width of opening portion 202a in second insulating layer 202 is greater than the width of opening portion 201a in first insulating layer 201.

The coefficient of linear thermal expansion of second insulating layer 202 is greater than the coefficient of linear thermal expansion of electron supply layer 104. The tensile stress of second insulating layer 202 is greater than the tensile stress of first insulating layer 201. In the present embodiment, the density of second insulating layer 202 is higher than the density of first insulating layer 201. In other words, the density of first insulating layer 201 is lower than the density of second insulating layer 202. Note that in the present embodiment, first insulating layer 201 and second insulating layer 202 are made of the same material, but the density of second insulating layer 202 is higher than the density of first insulating layer 201.

In the present embodiment, second insulating layer 202 is an SiN layer made of SiN, similarly to first insulating layer 201. Specifically, second insulating layer 202 is an SiN layer made of SiN and having a thickness of 10 nm, for example. Note that the thickness of second insulating layer 202 is not limited to 10 nm. For example, the thickness of second insulating layer 202 may be at least 10 nm and at most 30 nm. In the present embodiment, the thickness of second insulating layer 202 is greater than the thickness of first insulating layer 201, but is not limited to thereto. Thus, the thickness of second insulating layer 202 may be less than the thickness of first insulating layer 201. Furthermore, the thickness of second insulating layer 202 may increase from gate electrode 303 to contact layer 212. In this case, the thickness of second insulating layer 202 may continuously increase or discontinuously increase. Note that in the present embodiment, second insulating layer 202 is a single layer, but may be multilayered.

By configuring semiconductor device 1 with such a structure, the electron concentration of two-dimensional electron gas layer 105 can be made different for a portion in which second insulating layer 202 is present and a portion in which second insulating layer 202 is not present. Specifically, two-dimensional electron gas layer 105 includes first two-dimensional electron gas layer 105A in a portion that is not located below second insulating layer 202 and second two-dimensional electron gas layer 105B in a portion that is located below second insulating layer 202, and the electron concentration of second two-dimensional electron gas layer 105B is higher than the electron concentration of first two-dimensional electron gas layer 105A. Note that contact layer 212 in contact with second insulating layer 202 and second two-dimensional electron gas layer 105B are electrically connected by ohmic contact.

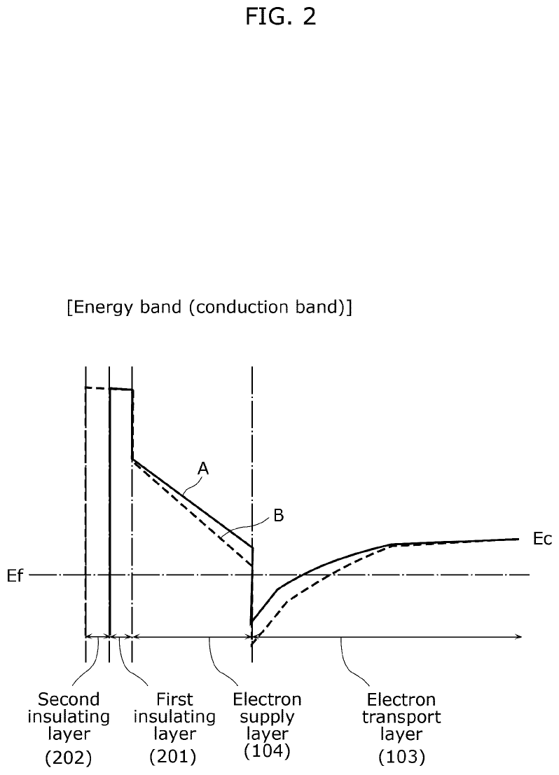

Here, the mechanism by which the electron concentration of second two-dimensional electron gas layer 105B is higher than the electron concentration of first two-dimensional electron gas layer 105A is described with reference to FIG. 2. FIG. 2 is a schematic diagram illustrating a conduction band of an energy band of semiconductor device 1 according to Embodiment 1.

In FIG. 2, solid line A represents a diagram of a portion corresponding to dash-dot line A in FIG. 1, and broken line B represents a diagram of a portion corresponding to dash-dot line B in FIG. 1. Thus, solid line A in FIG. 2 represents a diagram of a gate adjacent portion (that is, a portion in which second insulating layer 202 is not provided above first insulating layer 201, and only first insulating layer 201 is provided) that is a portion adjacent to gate electrode 303. Broken line B in FIG. 2 represents a diagram of a contact adjacent portion (that is, a portion in which second insulating layer 202 is provided above first insulating layer 201) that is a portion adjacent to contact layer 212.

As described above, in semiconductor device 1 in the present embodiment, the coefficient of linear thermal expansion of second insulating layer 202 is greater than the coefficient of linear thermal expansion of electron supply layer 104. Accordingly, tensile stress of the contact adjacent portion applied to electron supply layer 104 increases by providing second insulating layer 202 having a greater coefficient of linear thermal expansion than that of electron supply layer 104. Accordingly, the piezoelectric polarization in electron supply layer 104 increases, and a potential at an interface position between electron supply layer 104 and electron transport layer 103 decreases. As a result, an electron concentration of second two-dimensional electron gas layer 105B increases. Stated differently, the electron concentration of second two-dimensional electron gas layer 105B located below second insulating layer 202 is relatively higher than the electron concentration of first two-dimensional electron gas layer 105A not located below second insulating layer 202.

In this manner, since the electron concentration of second two-dimensional electron gas layer 105B is higher than the electron concentration of first two-dimensional electron gas layer 105A, a decrease in the electron concentration of a lateral-surface adjacent portion of each penetrating recessed portion 211 in electron supply layer 104 can be reduced. As a result, a decrease in maximum drain current can be reduced. In addition, since the electron concentration of the gate adjacent portion corresponding to first two-dimensional electron gas layer 105A is maintained, a leakage current between gate electrode 303 and drain electrode 302 can also be reduced. Thus, according to a configuration of semiconductor device 1 according to the present embodiment, a decrease in maximum drain current can be reduced and furthermore, leakage current between the gate and drain electrodes can be reduced. Since second insulating layer 202 greatly contributes to an increase in two-dimensional electron gas, a variation in drain current due to variations in the states of the lateral surfaces of penetrating recessed portions 211 (a variation in etching condition) can also be reduced.

Note that in semiconductor device 1 according to the present embodiment, second insulating layer 202 may contain oxygen. For example, second insulating layer 202 containing oxygen can be made of SiON or SiO₂, for instance.

In this manner, by making second insulating layer 202 a layer that contains oxygen such as an SiON or SiO₂ layer (an oxide layer, for instance), the thermal expansion coefficient of second insulating layer 202 can be made greater than that in the case where second insulating layer 202 is a nitride layer that contains nitrogen such as an SiN layer, so that the tensile stress of second insulating layer 202 can be further increased. Accordingly, the electron concentration of second two-dimensional electron gas layer 105B can be further made higher than the electron concentration of first two-dimensional electron gas layer 105A. Accordingly, a decrease in electron concentration of the lateral-surface adjacent portions of penetrating recessed portions 211 in electron supply layer 104 can be further reduced, and a decrease in maximum drain current can be further reduced.

In semiconductor device 1 according to the present embodiment, first insulating layer 201 and second insulating layer 202 may contain halogen such as fluorine (F) or chlorine (Cl), but nevertheless the halogen concentrations of first insulating layer 201 and second insulating layer 202 may be both at most 1×10¹⁸ atoms/cm³. This is because halogen contained in the semiconductor layer and the insulating layer has high electronegativity, and thus has a fixed negative charge. Accordingly, since the halogen concentration of first insulating layer 201 is at most 1×10¹⁸ atoms/cm³, the fixed negative charge in first insulating layer 201 can be decreased. Accordingly, an increase in potential at an interface position between electron supply layer 104 and electron transport layer 103 can be reduced, and thus a decrease in electron concentration of second two-dimensional electron gas layer 105B due to halogen can be reduced.

In semiconductor device 1 according to the present embodiment, the tensile stress of second insulating layer 202 is greater than the tensile stress of first insulating layer 201. Accordingly, the electron concentration of second two-dimensional electron gas layer 105B can be made further higher than the electron concentration of first two-dimensional electron gas layer 105A. Accordingly, a decrease in electron concentration of the lateral-surface adjacent portions of penetrating recessed portions 211 in electron supply layer 104 can be further reduced, and a decrease in maximum drain current can be further reduced. The thicker second insulating layer 202 is, the greater the tensile stress of second insulating layer 202 can be made. For example, the thickness of second insulating layer 202 may be greater than the thickness of first insulating layer 201.

Note that in semiconductor device 1 according to the present embodiment, first insulating layer 201 and second insulating layer 202 are made of the same material, and the density of second insulating layer 202 is higher than the density of first insulating layer 201. The mechanical strength is higher as the density of second insulating layer 202 is higher, and thus the tensile stress of second insulating layer 202 with respect to electron supply layer 104 is greater. Thus, the electron concentration of second two-dimensional electron gas layer 105B can be made still higher than the electron concentration of first two-dimensional electron gas layer 105A by making the density of second insulating layer 202 higher than the density of first insulating layer 201. Accordingly, a decrease in electron concentration of the lateral-surface adjacent portions of penetrating recessed portions 211 in electron supply layer 104 can be further reduced, and a decrease in maximum drain current can be further reduced.

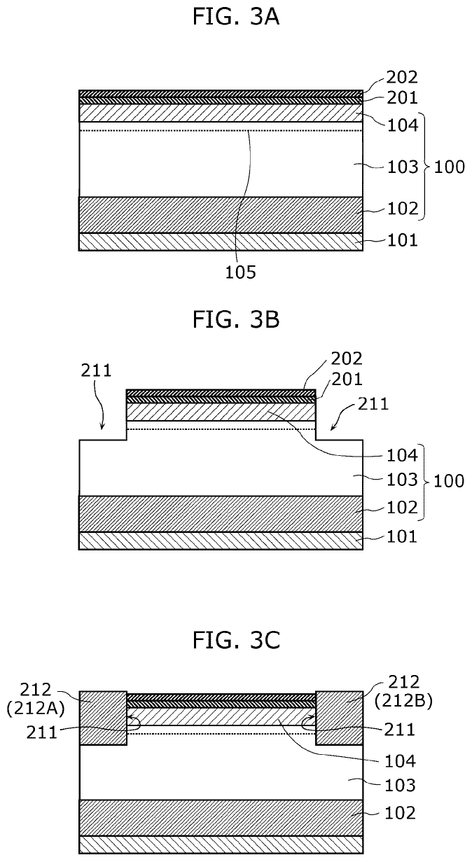

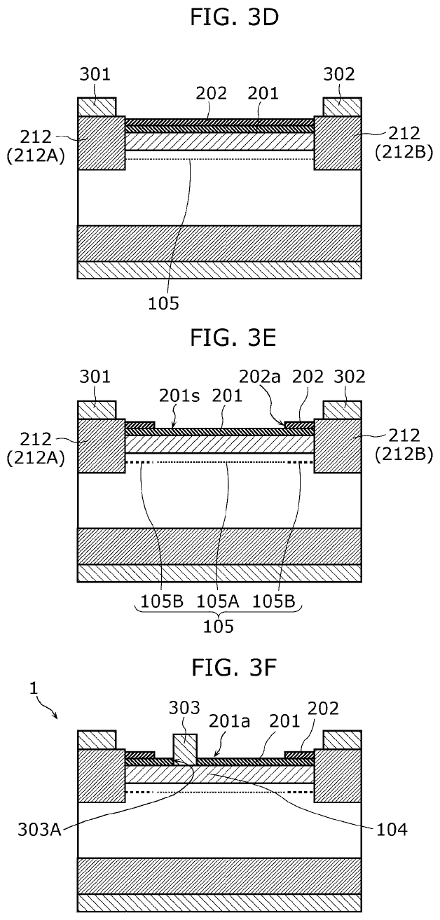

Next, a method for manufacturing semiconductor device 1 according to the present embodiment is described with reference to FIG. 3A to FIG. 3F. FIG. 3A to FIG. 3F are cross-sectional views illustrating processes of the method for manufacturing semiconductor device 1 according to Embodiment 1. FIG. 3A illustrates a process of forming semiconductor layered structure 100, first insulating layer 201, and second insulating layer 202. FIG. 3B illustrates a process of forming penetrating recessed portions 211. FIG. 3C illustrates a process of forming contact layer 212. FIG. 3D illustrates a process of forming source electrode 301 and drain electrode 302. FIG. 3E illustrates a process of patterning second insulating layer 202. FIG. 3F illustrates a process of forming gate electrode 303.

First, as illustrated in FIG. 3A, semiconductor layered structure 100 that includes buffer layer 102, electron transport layer 103, and electron supply layer 104 is formed above substrate 101 by using metal organic chemical vapor deposition (MOCVD) (a semiconductor layered structure forming process).

In the present embodiment, semiconductor layered structure 100 is formed above substrate 101 made of Si by sequentially epitaxially growing, in the +c plane direction (the <0001> direction), buffer layer 102 having a thickness of 2 um and a structure of stacked AlN and AlGaN layers, electron transport layer 103 having a thickness of 200 nm and made of GaN, and electron supply layer 104 having a thickness of 20 nm and made of AlGaN having an Al composition ratio of 25%.

Next, first insulating layer 201 made of SiN and second insulating layer 202 made of SiN are sequentially formed above semiconductor layered structure 100 (a process of forming the first insulating layer and the second insulating layer). In the present embodiment, after forming semiconductor layered structure 100, first insulating layer 201 and second insulating layer 202 are sequentially formed in the same semiconductor crystal growth device (MOCVD reactor). Thus, first insulating layer 201 is formed above electron supply layer 104 without exposing the inside of the reactor to the atmosphere, and second insulating layer 202 is formed above first insulating layer 201 without exposing the inside of the reactor to the atmosphere. In this manner, oxygen is not maldistributed between electron supply layer 104 and first insulating layer 201 by forming first insulating layer 201 directly above electron supply layer 104 without exposure to atmosphere. In this structure, a highly concentrated two-dimensional electron gas is generated on the electron transport layer 103 side of the heterointerface between electron supply layer 104 and electron transport layer 103, and two-dimensional electron gas layer 105 is formed.

Note that as a deposition condition for forming first insulating layer 201 and second insulating layer 202, for example, the growth temperature is in a range of 900° C. to 1150° C., and the source gases are SiH₄ and NH₃. Use of halogen may be avoided in dry-cleaning the MOCVD reactor so as not to have halogen mixed, as an impurity, into first insulating layer 201 and second insulating layer 202. Even if halogen is used in dry cleaning, halogen can be removed from the MOCVD reactor by using N₂ or NH₃, for instance, after the dry cleaning.

Next, as illustrated in FIG. 3B, penetrating recessed portions 211 are formed by removing portions of semiconductor layered structure 100 (a penetrating recessed portion forming process). In the present embodiment, since first insulating layer 201 and second insulating layer 202 are formed above semiconductor layered structure 100, portions of first insulating layer 201 and second insulating layer 202 are removed together with semiconductor layered structure 100.

Specifically, first, after applying a resist onto second insulating layer 202, the resist is patterned by the lithography method to form a mask (a resist mask) on a portion except regions of second insulating layer 202 in which contact layer 212 is to be formed (or stated differently, regions in which source electrode 301 and drain electrode 302 are to be formed). Thus, opening portions are formed in the regions of the resist in which contact layer 212 is to be formed. Specifically, the resist has opening portions in the regions in which source-side contact layer 212A and drain-side contact layer 212B are to be formed.

Next, dry etching is performed using the resist having such opening portions as a mask, to form penetrating recessed portions 211 that penetrate through first insulating layer 201, second insulating layer 202, and electron supply layer 104 and reach up to electron transport layer 103. Specifically, as illustrated in FIG. 3B, two penetrating recessed portions 211 are formed in correspondence with the regions in which source-side contact layer 212A and drain-side contact layer 212B are to be formed. Portions of electron transport layer 103 are exposed by forming penetrating recessed portions 211. After that, the mask (the resist) and a polymer generated in the dry etching are removed.

Note that penetrating recessed portions 211 are formed by dry etching in the present embodiment, but the method is not limited to this. Specifically, penetrating recessed portions 211 may be formed by wet etching.

Next, as illustrated in FIG. 3C, contact layer 212 is embedded and formed in penetrating recessed portions 211 (a contact layer forming process).

Specifically, n⁺-GaN is regrown by using MOCVD to fill two penetrating recessed portions 211 by using second insulating layer 202 as a mask. Accordingly, contact layer 212 made of n⁺-GaN can be selectively embedded and formed in two penetrating recessed portions 211. Note that contact layer 212 embedded in one of two penetrating recessed portions 211 is source-side contact layer 212A, and contact layer 212 embedded in the other of two penetrating recessed portions 211 is drain-side contact layer 212B.

In the present embodiment, Si is doped as an n-type impurity and n⁺-GaN is regrown to have a thickness of 100 nm, to form contact layer 212. The Si doping concentration of contact layer 212 is 2×10¹⁹/cm³, for example. Note that contact layer 212 may be formed not by being regrown but by sputtering, or may be formed by ion implantation and plasma treatment, for instance, without forming penetrating recessed portions 211.

Next, as illustrated in FIG. 3D, source electrode 301 and drain electrode 302 are formed above contact layer 212 so as to be in contact with contact layer 212 (a source electrode/drain electrode forming process).

Specifically, after forming a layered film by sequentially depositing a Ti film having a thickness of 30 nm and an Al film having a thickness of 200 nm by vapor deposition or sputtering, an unnecessary portion of the layered film is removed by the lift-off method, so that source electrode 301 and drain electrode 302 made of the layered film of the Ti film and the Al film and having predetermined shapes are formed above contact layer 212. In the present embodiment, source electrode 301 is formed above source-side contact layer 212A, and drain electrode 302 is formed above drain-side contact layer 212B. After that, the resist mask and the polymer are removed.

Next, a heat treatment is applied. Accordingly, two-dimensional electron gas layer 105 and contact layer 212 are electrically connected by ohmic contact.

Note that in the present embodiment, source electrode 301 and drain electrode 302 are formed by vapor deposition and the lift-off method, but are not limited to be formed thereby. For example, after a layered film is formed by sequentially depositing a Ti film and an Al film by sputtering, source electrode 301 and drain electrode 302 in predetermined shapes may be formed by patterning the layered film by using the lithography method and the dry etching method.

Next, as illustrated in FIG. 3E, a portion of second insulating layer 202 in which gate electrode 303 is to be provided is removed by patterning second insulating layer 202 (a second insulating layer patterning process).

Specifically, after applying the resist, the resist is patterned to have predetermined shapes by the lithography method, and a mask (a resist mask) that is continuous over regions in which source electrode 301 and drain electrode 302 are formed and regions separated from the region in which gate electrode 303 is to be formed (a region in which a gate-electrode is scheduled to be formed). In this case, in the plan view, an end portion of the patterned resist on the drain electrode 302 side is located between gate electrode 303 and contact layer 212, and an end portion of the patterned resist on the gate electrode 303 side is located between gate electrode 303 and contact layer 212. After that, a portion of second insulating layer 202 other than the portions in contact with contact layer 212 is removed by the dry etching method, so that first insulating layer 201 is exposed to form first insulating layer exposed portion 201s. At this time, second insulating layer 202 located below the patterned resist (the resist mask) is retained without being removed. Thus, the portions of second insulating layer 202 in contact with contact layer 212 are retained. After that, the resist and the polymer are removed. Accordingly, second insulating layer 202 having opening portion 202a can be formed in the region in which gate electrode 303 is to be formed. At this time, the electron concentration of a two-dimensional electron gas located below the portion in which second insulating layer 202 is not formed is low, and thus first two-dimensional electron gas layer 105A having a relatively low electron concentration of the two-dimensional electron gas and second two-dimensional electron gas layer 105B having a relatively high electron concentration of the two-dimensional electron gas are generated in two-dimensional electron gas layer 105.

Next, as illustrated in FIG. 3F, a portion of first insulating layer 201 that is a portion of first insulating layer exposed portion 201s of first insulating layer 201 separated from second insulating layer 202 is removed to form gate electrode 303 (a gate electrode forming process).

Specifically, after applying a resist above first insulating layer exposed portion 201s of first insulating layer 201, a mask (a resist mask) is formed in a region other than the region in which gate electrode 303 is to be formed (the region in which a gate-electrode is scheduled to be formed) by the lithography method. Subsequently, first insulating layer 201 is selectively removed by using the dry etching method to form opening portion 201a in first insulating layer 201 so that electron supply layer 104 is exposed. Next, the mask (the resist mask) and a polymer generated in the dry etching are removed. After that, gate electrode 303 is formed in opening portion 201a. Specifically, after forming a layered film in which a TiN film having a thickness of 50 nm and an Al film having a thickness of 450 nm are sequentially deposited by the sputtering method, the layered film is patterned by using the lithography method and the dry etching method to form gate electrode 303 in a predetermined shape illustrated in FIG. 3F. After that, the mask and a polymer generated in the dry etching are removed.

In this manner, semiconductor device 1 having a structure illustrated in FIG. 1 is completed through the series of processes in FIG. 3A to FIG. 3F.

Note that when second insulating layer 202 is formed in FIG. 3A, second insulating layer 202 may be formed at a temperature higher than that for first insulating layer 201. Stated differently, the temperature at which second insulating layer 202 is formed may be higher than the temperature at which first insulating layer 201 is formed. In other words, the temperature at which first insulating layer 201 is formed may be lower than the temperature at which second insulating layer 202 is formed. In this manner, even if first insulating layer 201 and second insulating layer 202 are made of the same material such as SIN, the tensile stress of second insulating layer 202 with respect to first insulating layer 201 can be further increased, and thus the electron concentration of second two-dimensional electron gas layer 105B can be further increased.

### Variation of Embodiment 1

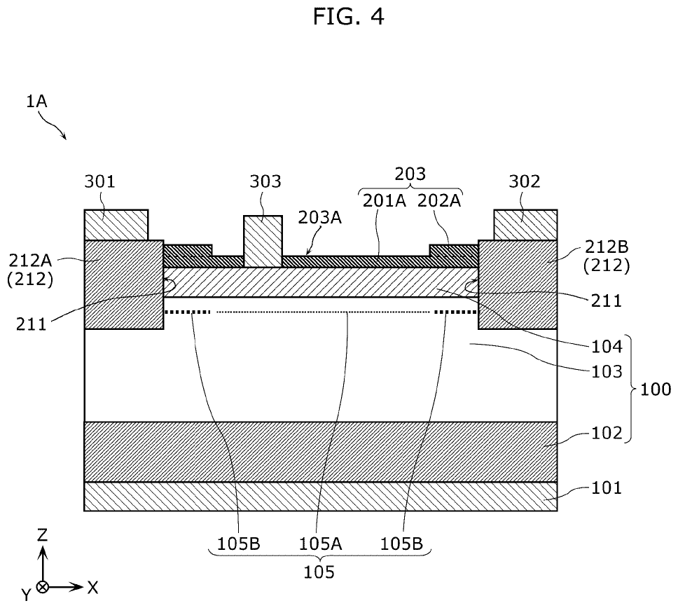

Next, a variation of Embodiment 1 is described with reference to FIG. 4. FIG. 4 is a cross-sectional view illustrating a configuration of semiconductor device 1A according to a variation of Embodiment 1.

As illustrated in FIG. 4, semiconductor device 1A according to this variation is different from semiconductor device 1 according to Embodiment 1 above in the configurations of first insulating layer 201A and second insulating layer 202A. Specifically, in semiconductor device 1 according to Embodiment 1 above, first insulating layer 201 and second insulating layer 202 are separate layers, but in semiconductor device 1A according to this variation, first insulating layer 201A and second insulating layer 202A are made of the same material, and also are configured of single insulating layer 203. Thus, in this variation, first insulating layer 201A and second insulating layer 202A are part of insulating layer 203. Thus, first insulating layer 201A is a first insulating layer portion in insulating layer 203, and second insulating layer 202A is a second insulating layer portion in insulating layer 203.

Specifically, insulating layer 203 is provided with recessed portion 203A. In insulating layer 203, a portion in which recessed portion 203A is provided (that is, a portion in which gate electrode 303 is formed) is included in only first insulating layer 201A (first insulating layer portion), and a portion in which recessed portion 203A is not provided is included in first insulating layer 201A (first insulating layer portion) and second insulating layer 202A (second insulating layer portion). Thus, a portion of insulating layer 203 in which second insulating layer 202A (second insulating layer portion) is present has a thickness greater than that of a portion of insulating layer 203 occupied by first insulating layer 201A (first insulating layer portion). As an example, the thickness of a portion of insulating layer 203 in which recessed portion 203A is formed is 5 nm, and the thickness of a portion of insulating layer 203 in which recessed portion 203A is not formed is 25 nm. Note that from the viewpoint of damage on electron supply layer 104 by dry etching, the thickness of a portion of insulating layer 203 in which recessed portion 203A is formed may be at least 2 nm.

When manufacturing semiconductor device 1A according to this variation, first insulating layer 201A and second insulating layer 202A are formed using the same material. Specifically, insulating layer 203 made of in-situ SiN and having a thickness of 25 nm is formed above electron supply layer 104, and subsequently recessed portion 203A is formed by dry etching to be separated from gate electrode 303. Accordingly, insulating layer 203 in a shape illustrated in FIG. 4 can be formed.

Semiconductor device 1A according to this variation can also yield effects similar to those yielded in Embodiment 1 above. Specifically, the electron concentration of second two-dimensional electron gas layer 105B is higher than the electron concentration of first two-dimensional electron gas layer 105A also in this variation. Accordingly, a decrease in electron concentration of the lateral-surface adjacent portions of penetrating recessed portions 211 in electron supply layer 104 can be reduced, and a decrease in maximum drain current can be reduced.

In this variation, first insulating layer 201A and second insulating layer 202A can be integrally formed using the same material, and thus semiconductor device 1A can be more readily produced as compared with Embodiment 1 above.

### Embodiment 2

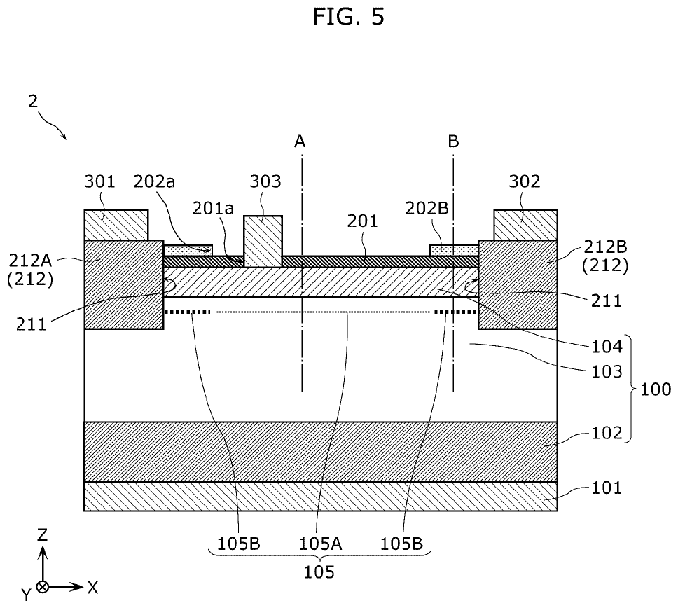

Next, semiconductor device 2 according to Embodiment 2 is described with reference to FIG. 5. FIG. 5 is a cross-sectional view illustrating a configuration of semiconductor device 2 according to Embodiment 2. Note that in the following, differences from Embodiment 1 are mainly described, and description of common points is omitted or simplified.

Semiconductor device 2 according to the present embodiment is different from semiconductor device 1 according to Embodiment 1 above in configuration of second insulating layer 202B. Specifically, second insulating layer 202 of semiconductor device 1 according to Embodiment 1 above is made of SiN, but second insulating layer 202B of semiconductor device 2 according to the present embodiment is made of an oxynitride layer such as an SiON layer. Note that semiconductor device 2 according to the present embodiment is also a high electron mobility transistor (HEMT) having a Schottky junction gate structure, similarly to Embodiment 1 above.

In the present embodiment, second insulating layer 202B is an SiON layer having a thickness of 20 nm. Note that the thickness of second insulating layer 202B is not limited to 20 nm. As an example, the thickness of second insulating layer 202B is at least 2 nm and at most 200 nm.

Note that second insulating layer 202B in the present embodiment is provided above first insulating layer 201 in contact with contact layer 212 but not in contact with gate electrode 303, similarly to second insulating layer 202 in Embodiment 1 above.

By configuring semiconductor device 2 with such a structure, the electron concentration of two-dimensional electron gas layer 105 can be made different for a portion in which second insulating layer 202B is present and a portion in which second insulating layer 202B is not present. Specifically, two-dimensional electron gas layer 105 includes first two-dimensional electron gas layer 105A in a portion that is not located below second insulating layer 202B and second two-dimensional electron gas layer 105B in a portion that is located below second insulating layer 202B, and the electron concentration of second two-dimensional electron gas layer 105B is higher than the electron concentration of first two-dimensional electron gas layer 105A.

By configuring semiconductor device 2 with such a structure, the electron concentration of two-dimensional electron gas layer 105 can be made different for a portion in which second insulating layer 202B is present and a portion in which second insulating layer 202B is not present, similarly to Embodiment 1 above. Specifically, two-dimensional electron gas layer 105 includes first two-dimensional electron gas layer 105A in a portion that is not located below second insulating layer 202B and second two-dimensional electron gas layer 105B in a portion that is located below second insulating layer 202B, and the electron concentration of second two-dimensional electron gas layer 105B is higher than the electron concentration of first two-dimensional electron gas layer 105A.

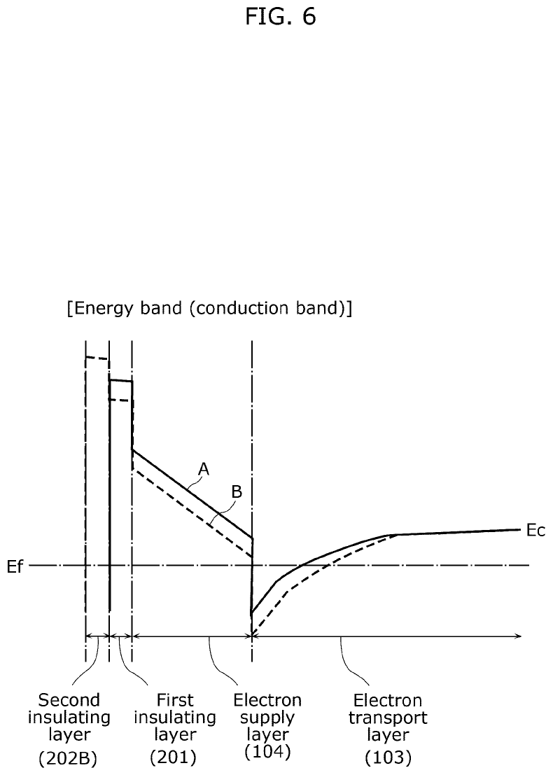

Here, in the present embodiment, the mechanism by which the electron concentration of second two-dimensional electron gas layer 105B is higher than the electron concentration of first two-dimensional electron gas layer 105A is described with reference to FIG. 6. FIG. 6 is a schematic diagram illustrating a conduction band of an energy band of semiconductor device 2 according to Embodiment 2.

In FIG. 6, solid line A represents a diagram of a portion corresponding to dash-dot line A in FIG. 5, and broken line B represents a diagram of a portion corresponding to dash-dot line B in FIG. 5. Thus, solid line A in FIG. 6 represents a diagram of a gate adjacent portion (that is, a portion in which second insulating layer 202B is not provided above first insulating layer 201, and only first insulating layer 201 is provided) that is a portion adjacent to gate electrode 303. Broken line B in FIG. 2 represents a diagram of a contact adjacent portion (a portion in which second insulating layer 202B is provided above first insulating layer 201) that is a portion adjacent to contact layer 212.

In the present embodiment, since second insulating layer 202B is made of an oxynitride layer such as an SiON layer, second insulating layer 202B has a fixed positive charge. Since second insulating layer 202B has a fixed positive charge, the potential of electron supply layer 104 decreases, and the potential at the boundary position between electron supply layer 104 and electron transport layer 103 decreases. Accordingly, the electron concentration of second two-dimensional electron gas layer 105B located below second insulating layer 202B increases. Stated differently, the electron concentration of second two-dimensional electron gas layer 105B is relatively higher than first two-dimensional electron gas layer 105A.

As described above, the electron concentration of second two-dimensional electron gas layer 105B can be made higher than the electron concentration of first two-dimensional electron gas layer 105A also in semiconductor device 2 according to the present embodiment. Accordingly, a decrease in electron concentration of the lateral-surface adjacent portions of penetrating recessed portions 211 in electron supply layer 104 can be reduced, and a decrease in maximum drain current can be reduced. Also in the present embodiment, since the electron concentration of the gate adjacent portion corresponding to first two-dimensional electron gas layer 105A is maintained, a leakage current between gate electrode 303 and drain electrode 302 can also be reduced. Thus, also in semiconductor device 2 according to the present embodiment, a decrease in the maximum drain current can be reduced and furthermore, the leakage current between the gate and drain electrodes can be reduced, similarly to Embodiment 1 above. Since second insulating layer 202 greatly contributes to an increase in two-dimensional electron gas, a variation in drain current due to variations in the states of the lateral surfaces of penetrating recessed portions 211 (a variation in etching condition) can also be reduced.

Note that in the present embodiment, second insulating layer 202B is configured of an oxynitride layer, but is not limited thereto. Specifically, second insulating layer 202B may be a composite layer made of an oxide and a nitride. Stated differently, second insulating layer 202B may be a composite layer of an oxide layer and a layer made of the same material as that of first insulating layer 201. For example, second insulating layer 202B may have a structure in which SiN, SiO₂, and SiN layers are stacked. As described above, second insulating layer 202B has a fixed positive charge even if second insulating layer 202B is not an oxynitride layer but is a composite layer with an oxide layer, so that the electron concentration of second two-dimensional electron gas layer 105B located below second insulating layer 202B increases and a decrease in maximum drain current can be reduced.

In this case, the SiO₂ film that is one layer of second insulating layer 202B may be an extremely thin interface oxide layer having a thickness of at most 1 nm. By adopting such a configuration, SiO₂ is induced by a nitride to have a fixed positive charge, and thus effects similar to those yielded when SiON having a fixed positive charge is used can be yielded.

In semiconductor device 2 according to the present embodiment, second insulating layer 202B may include an n-type semiconductor layer. The n-type semiconductor layer included in second insulating layer 202B may be made of a group III semiconductor such as n-type GaN or may be made of a group IV semiconductor such as n-type polysilicon, for example. In this manner, since second insulating layer 202B includes an n-type semiconductor layer, the electron concentration of second two-dimensional electron gas layer 105B is higher than that of first two-dimensional electron gas layer 105A. Accordingly, a decrease in electron concentration of the lateral-surface adjacent portions of penetrating recessed portions 211 in electron supply layer 104 can be reduced, and a decrease in maximum drain current can be reduced.

Similarly to Embodiment 1 above, the halogen concentration of first insulating layer 201 may be at most 1×10¹⁸ atoms/cm³ also in semiconductor device 2 according to the present embodiment. By adopting such a configuration, the fixed negative charge in first insulating layer 201 can be decreased, a rise in potential at the interface position between electron supply layer 104 and electron transport layer 103 can be reduced, and decreases in electron concentrations of first two-dimensional electron gas layer 105A and second two-dimensional electron gas layer 105B due to halogen can be reduced.

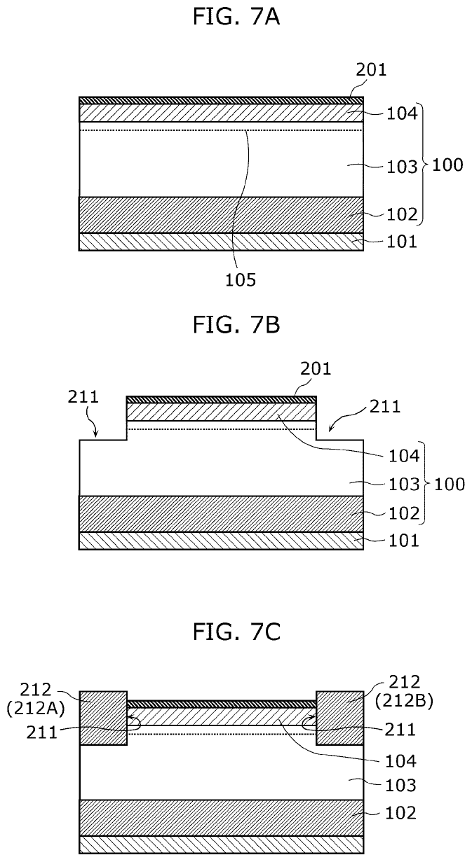

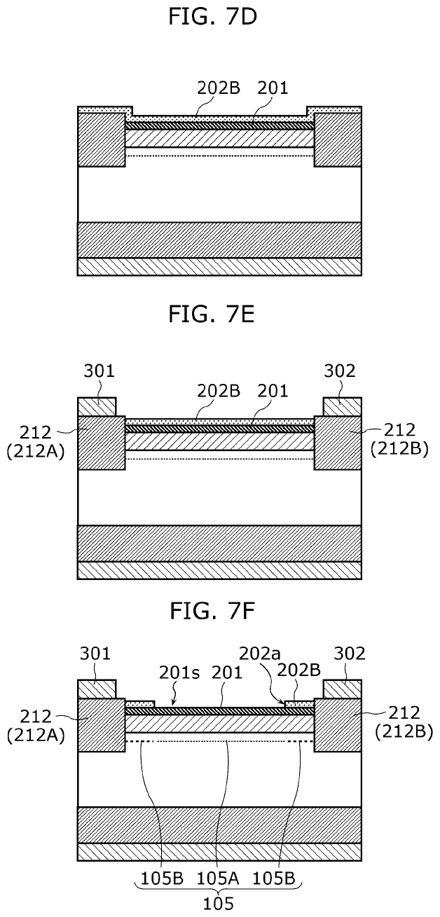

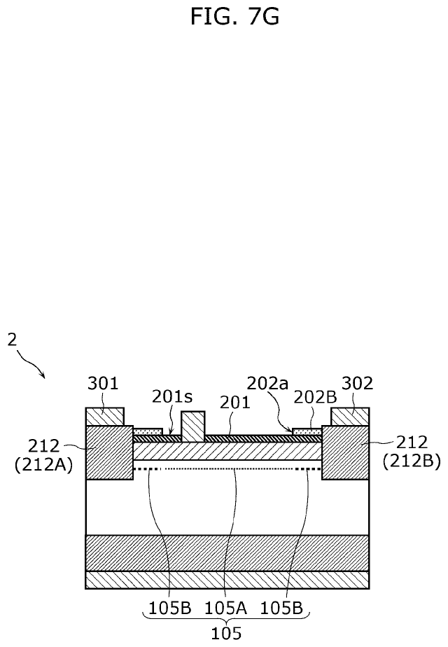

Next, a method for manufacturing semiconductor device 2 according to the present embodiment is described with reference to FIG. 7A to FIG. 7G. FIG. 7A to FIG. 7G are cross-sectional views illustrating processes of the method for manufacturing semiconductor device 2 according to Embodiment 2. FIG. 7A illustrates a process of forming semiconductor layered structure 100 and first insulating layer 201. FIG. 7B illustrates a process of forming penetrating recessed portions 211. FIG. 7C illustrates a process of forming contact layer 212. FIG. 7D illustrates a process of forming second insulating layer 202B. FIG. 7E illustrates a process of forming source electrode 301 and drain electrode 302. FIG. 7F illustrates a process of patterning second insulating layer 202B. FIG. 7G illustrates a process of forming gate electrode 303.

First, as illustrated in FIG. 7A, similarly to Embodiment 1 above, semiconductor layered structure 100 that includes buffer layer 102, electron transport layer 103, and electron supply layer 104 is formed above substrate 101 by MOCVD.

Next, first insulating layer 201 is formed above semiconductor layered structure 100 (a first insulating layer forming process). In the present embodiment, after forming semiconductor layered structure 100, first insulating layer 201 is sequentially formed in the same semiconductor crystal growth device (MOCVD reactor). Thus, first insulating layer 201 is formed above electron supply layer 104 without exposing the inside of the reactor to the atmosphere. In this manner, oxygen is not maldistributed between electron supply layer 104 and first insulating layer 201 by forming first insulating layer 201 above electron supply layer 104 without exposure to the atmosphere. In this structure, a highly concentrated two-dimensional electron gas is generated on the electron transport layer 103 side of the heterointerface between electron supply layer 104 and electron transport layer 103, and two-dimensional electron gas layer 105 is formed.

Next, as illustrated in FIG. 7B, penetrating recessed portions 211 are formed by removing portions of semiconductor layered structure 100 (a penetrating recessed portion forming process). In the present embodiment, since first insulating layer 201 is formed above semiconductor layered structure 100, portions of first insulating layer 201 are removed together with semiconductor layered structure 100.

Specifically, after applying a resist onto first insulating layer 201, the resist is patterned by the lithography method to form a mask on a portion except regions in which contact layer 212 is formed (or stated differently, regions in which source electrode 301 and drain electrode 302 are formed). Thus, opening portions are formed in the regions of the resist in which contact layer 212 is formed. Specifically, opening portions are formed in the regions in which source-side contact layer 212A and drain-side contact layer 212B are formed.

Next, dry etching is performed using the resist having such opening portions as a mask, to form penetrating recessed portions 211 that penetrate through first insulating layer 201 and electron supply layer 104 and reach up to electron transport layer 103. Specifically, as illustrated in FIG. 7B, two penetrating recessed portions 211 are formed in correspondence with the regions in which source-side contact layer 212A and drain-side contact layer 212B are formed. Portions of electron transport layer 103 are exposed by forming penetrating recessed portions 211. After that, the mask (the resist) and a polymer generated by the dry etching are removed.

Next, as illustrated in FIG. 7C, contact layer 212 is embedded and formed in penetrating recessed portions 211 (a contact layer forming process).

Specifically, n⁺-GaN is regrown by using MOCVD to fill two penetrating recessed portions 211 by using first insulating layer 201 as a mask, similarly to Embodiment 1 above. Accordingly, contact layer 212 made of n⁺-GaN can be selectively embedded and formed in two penetrating recessed portions 211. Note that contact layer 212 embedded in one of two penetrating recessed portions 211 is source-side contact layer 212A, and contact layer 212 embedded in the other of two penetrating recessed portions 211 is drain-side contact layer 212B.

Next, as illustrated in FIG. 7D, second insulating layer 202B is formed above first insulating layer 201 (a second insulating layer forming process).

Specifically, second insulating layer 202B made of SiON as an oxynitride and having a thickness of 20 nm is formed above first insulating layer 201. A deposition condition for forming second insulating layer 202B is, for example, a growth temperature of 900° C. to 1150° C., and SiH₄ and NH₃ may be used as source gases.

Note that second insulating layer 202B made of SiON may be formed by being subjected to a heat treatment at a temperature of at most 800° C. under oxygen and nitrogen atmosphere after an SiO₂ layer is formed. Also in this case, second insulating layer 202B having a fixed positive charge and made of SiON can be formed. Rather than performing a heat treatment, a plasma nitriding treatment in which NH₃ plasma is used may be performed to form second insulating layer 202B having a fixed positive charge and made of SiON, after forming an SiO₂ layer.

Next, as illustrated in FIG. 7E, source electrode 301 and drain electrode 302 are formed above contact layer 212 so as to be in contact with contact layer 212 (a source electrode/drain electrode forming process).

Specifically, after exposing contact layer 212 by removing a portion of second insulating layer 202B, similarly to Embodiment 1 above, a layered film is formed by sequentially depositing a Ti film and an Al film by vapor deposition. After that, an necessary portion of the layered film is removed by the lift-off method so that source electrode 301 and drain electrode 302 made of a layered film of a Ti film and an Al film and having predetermined shapes can be formed above contact layer 212. In the present embodiment, source electrode 301 is formed above source-side contact layer 212A, and drain electrode 302 is formed above drain-side contact layer 212B.

After that, by performing a heat treatment, two-dimensional electron gas layer 105 and contact layer 212 are electrically connected by ohmic contact.

Next, as illustrated in FIG. 7F, a portion of second insulating layer 202B in which gate electrode 303 is to be provided is removed by patterning second insulating layer 202B (a second insulating layer patterning process).

Specifically, after applying the resist, the resist is patterned to have predetermined shapes by the lithography method, and a mask (a resist mask) that is continuous over regions in which source electrode 301 and drain electrode 302 are formed and regions separated from a region in which gate electrode 303 is to be formed (a region in which a gate-electrode is scheduled to be formed), similarly to Embodiment 1 above. After that, a portion of second insulating layer 202B other than portions in contact with contact layer 212 is removed by the dry etching method, so that first insulating layer 201 is exposed to form first insulating layer exposed portion 201s. At this time, second insulating layer 202B located below the patterned resist (the resist mask) is retained without being removed. Thus, portions of second insulating layer 202B in contact with contact layer 212 are retained. After that, the resist and the polymer are removed. Accordingly, second insulating layer 202B having opening portion 202a can be formed in the region in which gate electrode 303 is to be formed. At this time, the electron concentration of a two-dimensional electron gas located below the portion in which second insulating layer 202B is not formed is low, and thus first two-dimensional electron gas layer 105A having a relatively low electron concentration of the two-dimensional electron gas and second two-dimensional electron gas layer 105B having a relatively high electron concentration of the two-dimensional electron gas are generated in two-dimensional electron gas layer 105.

Next, as illustrated in FIG. 7G, a portion of first insulating layer 201 that is a portion of first insulating layer exposed portion 201s separated from second insulating layer 202B is removed to form gate electrode 303 (a gate electrode forming process). Specifically, gate electrode 303 can be formed in a manner similar to that in Embodiment 1 above.

Accordingly, semiconductor device 2 having a structure illustrated in FIG. 4 is completed through the series of processes in FIG. 7A to FIG. 7G.

Note that when second insulating layer 202B is formed in the process of FIG. 7D, a temperature at which second insulating layer 202 is formed may be higher than the temperature at which first insulating layer 201 is formed. Thus, the temperature at which first insulating layer 201 is formed may be lower than the temperature at which second insulating layer 202B is formed. Accordingly, the tensile stress of second insulating layer 202B with respect to first insulating layer 201 can be increased, and thus the electron concentration of second two-dimensional electron gas layer 105B can be further increased.

### Other Variations

The semiconductor devices according to the present disclosure have been described in the above, based on Embodiments 1 and 2, but the present disclosure is not limited to Embodiment 1 or 2.

For example, electron transport layer 103 and electron supply layer 104 are made of group III nitride semiconductors in Embodiments 1 and 2 above, but the material is not limited thereto. Specifically, electron transport layer 103 and electron supply layer 104 may be made of other semiconductor materials such as a group III arsenide semiconductor.

In Embodiment 1 above, second insulating layer 202 is made of SiN, but the material is not limited thereto. For example, in Embodiment 1 above, second insulating layer 202 may be a layer that contains oxygen such as an SiON or SiO₂ layer. Accordingly, as compared to the case in which second insulating layer 202 is an SiN layer, the thermal expansion coefficient of second insulating layer 202 can be increased. Accordingly, the tensile stress of second insulating layer 202 can be further increased, and the electron concentration of second two-dimensional electron gas layer 105B can be made further higher than the electron concentration of first two-dimensional electron gas layer 105A. Accordingly, a decrease in electron concentration of the lateral-surface adjacent portions of penetrating recessed portions 211 in electron supply layer 104 can be further reduced, and a decrease in maximum drain current can be further reduced. Furthermore, in Embodiment 1 above, since second insulating layer 202 is an SiON layer, second insulating layer 202 can be made a layer having a fixed positive charge, similarly to Embodiment 2 above. Accordingly, the electron concentration of second two-dimensional electron gas layer 105B located below second insulating layer 202 further increases, and a decrease in maximum drain current can be further reduced.

In Embodiment 2 above, similarly to Embodiment 1 above, the coefficient of linear thermal expansion of second insulating layer 202B can be made greater than the coefficient of linear thermal expansion of electron supply layer 104, and the tensile stress of second insulating layer 202B may be made greater than the tensile stress of first insulating layer 201. Accordingly, the electron concentration of second two-dimensional electron gas layer 105B can be further increased, so that a decrease in maximum drain current can be further reduced.

The present disclosure also encompasses embodiments as a result of adding, to the embodiments, various modifications that may be conceived by those skilled in the art, and embodiments obtained by combining elements and functions in the embodiments without departing from the purport of the present disclosure. The present disclose also encompasses any combination of two or more claims within a technically consistent range among the claims stated in the claim section of the present application as originally filed. For example, when the dependent claims recited in the claim section of the present application as originally filed are made multiple dependent claims or multiple dependent claims that are dependent from multiple dependent claims, the present disclosure also encompasses all the combinations of the claims in the multiple dependent claims or the multiple dependent claims that are dependent from multiple dependent claims.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### INDUSTRIAL APPLICABILITY

The technology of the present disclosure can be used as a semiconductor device such as a switching transistor used in a communication device and an inverter for which a high-speed operation is expected and a power supply circuit. Among the above, the technology of the present disclosure is useful in particular to a high frequency power device having a great influence on heat generated due to an ohmic contact resistance.

1. A semiconductor device comprising:
an electron transport layer;
an electron supply layer provided above the electron transport layer and having a band gap greater than a band gap of the electron transport layer;
a gate electrode provided above the electron supply layer;
a source-side contact layer and a drain-side contact layer that are embedded in recessed portions that penetrate through the electron supply layer, at positions between which the gate electrode is provided;
a first insulating layer provided above a portion of the electron supply layer in which the gate electrode is not provided; and
a second insulating layer provided above the first insulating layer, in contact with the source-side contact layer and/or the drain-side contact layer, and not in contact with the gate electrode,
wherein a coefficient of linear thermal expansion of the second insulating layer is greater than a coefficient of linear thermal expansion of the electron supply layer, and
the first insulating layer and the second insulating layer both have a halogen concentration of at most 1×10¹⁸ atoms/cm³.

2. The semiconductor device according to claim 1,
wherein oxygen is not maldistributed between the first insulating layer and the electron supply layer.

3. The semiconductor device according to claim 1,
wherein the first insulating layer includes no oxygen.

4. The semiconductor device according to claim 1,
wherein the second insulating layer includes oxygen.

5. The semiconductor device according to claim 1,
wherein in a cross-sectional view, the second insulating layer has a width of at most 1 μm.

6. The semiconductor device according to claim 1,
wherein the second insulating layer has a tensile stress greater than a tensile stress of the first insulating layer.

7. The semiconductor device according to claim 1,
wherein the first insulating layer and the second insulating layer are made of a same material, and
the first insulating layer has a density lower than a density of the second insulating layer.

8. The semiconductor device according to claim 1,
wherein the electron transport layer and the electron supply layer are each made of a group III nitride semiconductor.

9. A semiconductor device comprising:
an electron transport layer;
an electron supply layer provided above the electron transport layer and having a band gap greater than a band gap of the electron transport layer;
a gate electrode provided above the electron supply layer;
a contact layer embedded in recessed portions that penetrate through the electron supply layer, at positions between which the gate electrode is provided;
a source electrode or a drain electrode provided above the contact layer;
a first insulating layer provided above a portion of the electron supply layer in which the gate electrode is not provided; and
a second insulating layer provided above the first insulating layer, in contact with the contact layer, and not in contact with the gate electrode,
wherein the second insulating layer includes an oxynitride layer or a composite layer made of an oxide and a nitride, and the first insulating layer has a halogen concentration of at most 1×10¹⁸ atoms/cm³.

10. The semiconductor device according to claim 9,
wherein the second insulating layer includes an n-type semiconductor layer.

11. The semiconductor device according to claim 9,
wherein the electron transport layer and the electron supply layer are each made of a group III nitride semiconductor.

12. A semiconductor device comprising:
an electron transport layer;
an electron supply layer provided above the electron transport layer and having a band gap greater than a band gap of the electron transport layer;
a gate electrode provided above the electron supply layer;
a source-side contact layer and a drain-side contact layer that are embedded in recessed portions that penetrate through the electron supply layer, at positions between which the gate electrode is provided;
a first insulating layer provided above a portion of the electron supply layer in which the gate electrode is not provided; and
a second insulating layer provided above the first insulating layer, in contact with the source-side contact layer and/or the drain-side contact layer, and not in contact with the gate electrode,
wherein a coefficient of linear thermal expansion of the second insulating layer is greater than a coefficient of linear thermal expansion of the electron supply layer, and
in a cross-sectional view, the second insulating layer has a width of at most 1 μm.

13. The semiconductor device according to claim 12,
wherein oxygen is not maldistributed between the first insulating layer and the electron supply layer.

14. The semiconductor device according to claim 12,
wherein the first insulating layer includes no oxygen.

15. The semiconductor device according to claim 12,
wherein the second insulating layer includes oxygen.

16. The semiconductor device according to claim 12,
wherein the first insulating layer and the second insulating layer both have a halogen concentration of at most 1×10¹⁸ atoms/cm³.

17. The semiconductor device according to claim 12,
wherein the second insulating layer has a tensile stress greater than a tensile stress of the first insulating layer.

18. The semiconductor device according to claim 12,
wherein the first insulating layer and the second insulating layer are made of a same material, and
the first insulating layer has a density lower than a density of the second insulating layer.

19. The semiconductor device according to claim 12,
wherein the electron transport layer and the electron supply layer are each made of a group III nitride semiconductor.
